(19) United States
(12) Patent Application Publication
(10) Pub. No.: US 2024/0308841 A1
(43) Pub. Date: Sep. 19, 2024

(54) MEMS DEVICE AND MANUFACTURING METHOD FOR MEMS DEVICE

(71) Applicant: ROHM CO., LTD., Kyoto (JP)

(72) Inventors: Toma FUJITA, Kyoto (JP); Martin Wilfried HELLER, Kyoto (JP); Daisuke KAMINISHI, Kyoto (JP); Naoki IZUMI, Kyoto (JP)

(73) Assignee: ROHM CO., LTD., Kyoto (JP)

(21) Appl. No.: 18/601,334

(22) Filed: Mar. 11, 2024

(30) Foreign Application Priority Data
Mar. 14, 2023 (JP) 2023-040056

(51) Int. Cl. B81B 3/00

(52) U.S. Cl. CPC B81B 3/0021; B81B 2201/0235; B81B 2203/0163; B81B 2203/0307; B81B 2203/04; B81B 2207/07

(57) ABSTRACT

The present disclosure provides a MEMS device including a device wafer, a cap wafer and a bonding layer. The device wafer includes: a device substrate, having a first main surface, a second main surface opposite to the first main surface, and a cavity recessed along a first direction from the first main surface toward the second main surface; a sensor unit, located within the cavity and mechanically connected to and electrically insulated from the device substrate by a single anchor; and a device wiring, electrically coupled to the sensor unit. The cap wafer includes: a cap substrate, facing the device wafer from a side of the first main surface; and a cap wiring, electrically coupled to the device wiring. The bonding layer bonds the device wafer with the cap wafer, and the device wiring is directly connected to the bonding layer.

### TECHNICAL FIELD

The present disclosure relates to a micro-electro-mechanical systems (MEMS) device and a method for manufacturing a MEMS device.

### BACKGROUND

It is known that MEMS sensors manufactured by means of semiconductor microfabrication techniques are available. An acceleration sensor as a MEMS sensor is disclosed by patent publication 1. The acceleration sensor of patent publication 1 includes capacitor unit having a fixed electrode and a mobile electrode, and detects an acceleration by detecting a change in a static capacitance of the capacitor unit, wherein the change in the static capacitance of the capacitor unit corresponds to a movement of the mobile electrode in response to the acceleration exerted.

### PRIOR ART DOCUMENT

### Patent Publication

[Patent document 1] Japan Patent Publication No. 2015-217473

### BRIEF DESCRIPTION OF THE DRAWINGS

FIG. 1 is a plan view of a MEMS device according to an embodiment of the present disclosure.

FIG. 2 is a cross-sectional diagram of the MEMS device in FIG. 1 in an X-Z plane along a section line II-II.

FIG. 3 is a bottom view obtained by viewing a device wafer from a Z2 side.

FIG. 4 is a plan view obtained by viewing a device wafer from a Z1 side.

FIG. 5 is a cross-sectional diagram of the MEMS device in FIG. 1 in a Y-Z plane along a section line V-V.

FIG. 6 is a diagram showing one of forming processes of a cap wafer.

FIG. 7 is a diagram showing a subsequent process of FIG. 6.

FIG. 8 is a diagram showing a subsequent process of FIG. 7.

FIG. 9 is a diagram showing a subsequent process of FIG. 8.

FIG. 10 is a diagram showing a subsequent process of FIG. 9.

FIG. 11 is a diagram showing a subsequent process of FIG. 10.

FIG. 12 is a diagram showing a subsequent process of FIG. 11.

FIG. 13 is a diagram showing one of forming processes of a device wafer.

FIG. 14 is a diagram showing a subsequent process of FIG. 13.

FIG. 15 is a diagram showing a subsequent process of FIG. 14.

FIG. 16 is a diagram showing a subsequent process of FIG. 15.

FIG. 17 is a diagram showing a subsequent process of FIG. 16.

FIG. 18 is a diagram showing one of bonding processes of a cap wafer and a device wafer.

FIG. 19 is a diagram showing a subsequent process of FIG. 18.

FIG. 20 is a diagram showing a subsequent process of FIG. 19.

FIG. 21 is a diagram showing a subsequent process of FIG. 20.

FIG. 22 is a diagram showing a variation example of a MEMS device similar to FIG. 2.

FIG. 23 is a diagram showing another variation example of a MEMS device similar to FIG. 3.

FIG. 24 is a cross-sectional diagram of the MEMS device in FIG. 23 in an X-Z plane along a section line XXIV-XXIV.

FIG. 25 is a diagram showing yet another variation example of a MEMS device similar to FIG. 3.

FIG. 26 is a cross-sectional diagram of the MEMS device in FIG. 25 in an X-Z plane along a section line XXVI-XXVI.

### DETAILED DESCRIPTION OF THE EMBODIMENTS

Details of a MEMS device according to an embodiment of the present disclosure are given with the accompanying drawings below. Moreover, the description below are essentially exemplary, and the present disclosure does not intend to limit applications or uses thereof. In addition, the accompanying drawings are schematic diagrams, in which sizes and scales may be different from those of actual objects.

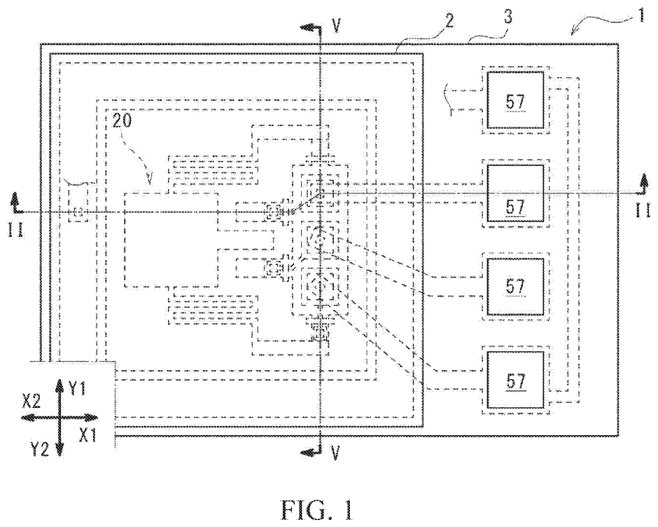

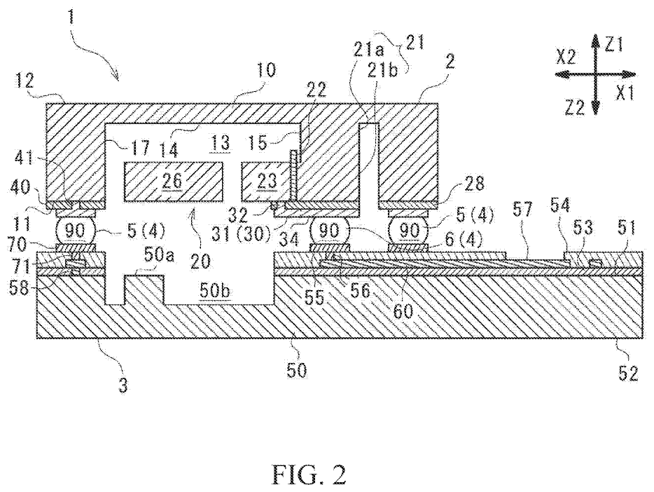

FIG. 1 shows a plan view of a MEMS device 1 according to an embodiment of the present disclosure. The MEMS device 1 is a MEMS sensor manufactured by a semiconductor microprocessing technology. FIG. 2 shows a cross-sectional diagram of the MEMS device 1 along a line II-II.

In the description below, for illustration purposes, left and right directions along sides of the MEMS device 1 in the plan view shown in FIG. 1 are referred to an X direction, up and down directions are referred to as a Y direction, and a thickness direction (up and down directions) of the MEMS device 1 in the cross-sectional diagram shown in FIG. 2 is referred to as a Z direction. More particularly, the right side in FIG. 1 is referred to as an X1 side, the left side is referred to as an X2 side, the upper side is referred to as a Y1 side, and the lower side is referred to as a Y2 side. The upper side in FIG. 2 is referred to as a Z1 side, and the lower side is referred to as a Z2 side.

### [Overall Configuration of MEMS Device]

As shown in FIG. 1 and FIG. 2, the MEMS device 1 includes a device wafer 2 located on the Z1 side and having a sensor unit 20, a cap wafer 3 located on the Z2 side with respect to the device wafer 2, and a bonding layer 4 bonding the device wafer 2 to the cap wafer 3.

### [Device Wafer]

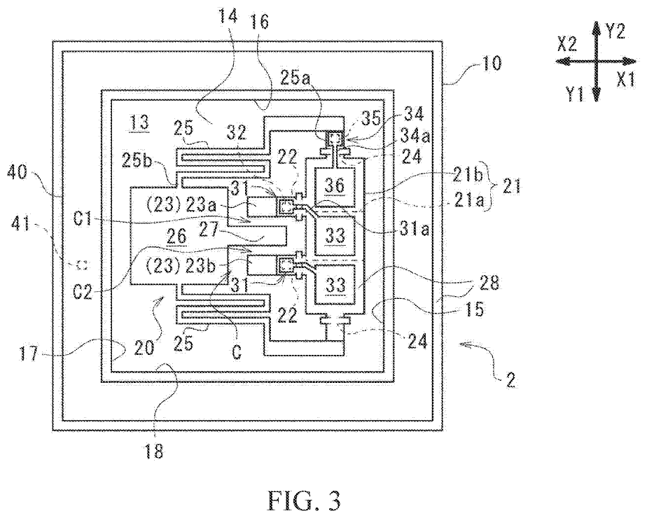

FIG. 3 shows a bottom view obtained by viewing the device wafer 2 from the Z2 side. As shown in FIG. 2 and FIG. 3, the device wafer 2 includes: a device substrate 10, having a first main surface 11 located on the Z2 side and extending in parallel to the X direction and the Y direction, a second main surface 12 located on a side opposite to the first main surface 11, that is, the Z1 side, and extending in parallel to the X direction and the Y direction, and a cavity 13 recessed from the first main surface 11 to the Z1 side; the sensor unit 20, located within the cavity 13; and a device wiring 30, electrically coupled to the sensor unit 20.

The device substrate 10 is made of silicon doped with high-concentration p-type impurities or n-type impurities, and is conductive.

A peripheral wall defining the cavity 13 includes a rectangular bottom wall 14, a first vertical wall 15 extending from an edge on the X1 side of the bottom wall 14 to the Z2 side, a second vertical wall 16 extending from an edge on the Y2 side of the bottom wall 14 to the Z2 side, a third vertical wall 17 extending from an edge on the X2 side of the bottom wall 14 to the Z2 side, and a fourth vertical wall 18 extending from an edge on the Y1 side of the bottom wall 14 to the Z2 side.

The sensor unit 20 includes an anchor 21 fixed at the bottom wall 14, a fixed electrode 23 connected to the anchor 21, a spring 25 connected to the anchor 21, a mass 26 supported by the spring 25, and a movable electrode 27 connected to the mass 26.

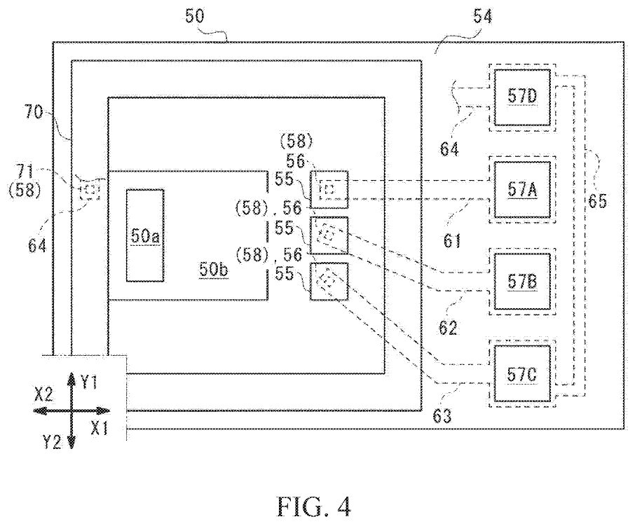

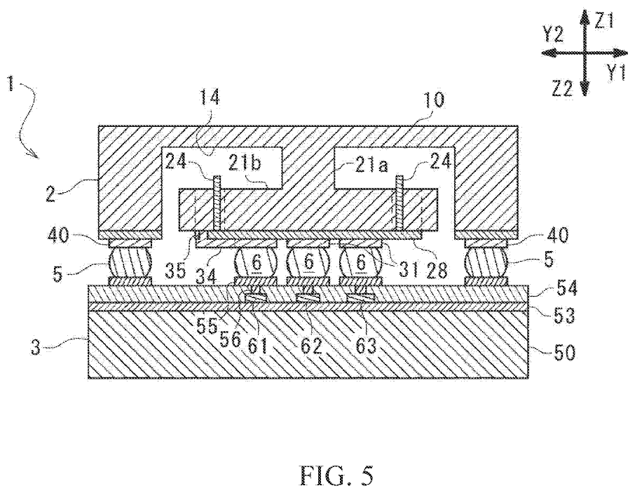

FIG. 5 shows a cross-sectional diagram of the anchor 21 in FIG. 1 in a Y-Z plane along the section line V-V. In combination with reference to FIG. 5, the anchor 21 extends from the bottom wall 14 to the Z2 side, and is separated from any one of the vertical walls 15 to 18. The anchor 21 includes a base end 21a located on the Z1 side and fixed on the bottom wall 14, and a main body 21b located on the Z2 side of the base end 21a. In this embodiment, the base end 21a is smaller than the main body 21b along the Y direction. That is, the anchor 21 has the base end 21a, which is smaller than the main body 21b, fixed at the bottom wall 14, so transmission of packaging stress to the anchor 21 is suppressed.

In this embodiment, the fixed electrode 23 is provided in a pair and arranged along the Y direction on the X2 side of the anchor 21, and includes a first fixed electrode 23a and a second fixed electrode 23b individually extending along the X direction. The pair of fixed electrodes 23 are individually mechanically connected to the anchor 21 via a first isolation joint (to be referred to as IJ below) 22 and electrically insulated.

In this embodiment, the spring 25 is provided in a pair which have the base ends 25a connected to both the Y1 side and the Y2 side of the anchor 21, and the pair of springs 25 individually extend flexibly along the Y direction, for example, extending along the Y direction by bending along the X direction multiple times. The pair of springs 25 are individually mechanically connected to the anchor 21 via a second IJ 24 and electrically insulated.

The mass 26 is supported between front ends 25b of the pair of springs 25, and can move along the Y direction against an elastic force of the springs 25 when an inertial force is generated.

The movable electrode 27 is connected to the mass 26, and extends along the X direction, at a position at the middle of the pair of fixed electrodes 23 along the Y direction and at a same height along the Z direction. In the description below, sometimes the springs 25 mechanically connected to the anchor 21 via a second IJ 24 and electrically insulated, the mass 26 and the movable electrode 27 are collectively referred to as the movable electrode 27.

All of the anchor 21, the first IJ 22, the fixed electrodes 23, the springs 25, the mass 26 and the movable electrode 27 are formed from the device substrate 10 and are conductive. Moreover, all of the first IJ 22, the fixed electrodes 23, the springs 25, the mass 26 and the movable 27 are released from the bottom wall 14 and spaced apart from the Z2 side.

In the sensor unit 20, a capacitor C includes one pair of fixed electrodes 23 and the movable electrode 27. More specifically, a first capacitor C1 includes the first fixed electrode 23a and the movable electrode 27, and a second capacitor C2 includes the second fixed electrode 23b and the movable electrode 27.

The sensor unit 20 of the present disclosure is configured as an acceleration sensor. The acceleration sensor moves the movable electrode 27 along the Y direction when an acceleration is generated along the Y direction, increases a static capacitance of one of the first capacitor C1 and the second capacitor C2 and decreases a static capacitance of the other, and detects a change in the static capacitance via an electrode pad 57 to be described below so as to detect an acceleration along the Y direction. Moreover, the sensor unit 20 can also be configured to detect an electrical signal that depends on an inertial force, such as acceleration along the X direction or an acceleration along the Z direction. That is, the sensor unit 20 of the present disclosure only needs to be a sensor unit in which a plurality of electrodes are electrically insulated from one another and mechanically supported by a single anchor.

A device insulating layer 28 is laminated on the first main surface 11 of the device substrate 10 from the Z2 side. The device insulating layer 28 is made of silicon oxide (SiO). The device insulating layer 28 is also laminated, in the sensor unit 20, on at least a region of a proximal side of the first IJ 22 in the anchor 21 and the fixed electrode 23, disposed on at least a region spanning the spring 25, the mass 26 and the movable electrode 27, and located on a proximal side of the second IJ 24.

In this embodiment, on the fixed electrode 23, the device insulating layer 28 has a region where a fixed electrode contact 32, which will be described later, is arranged at a position beyond the first IJ 22 from the anchor 21 to the X2 side and immediately terminates. Similarly, on the movable electrode 25, on the pair of springs 25 of this embodiment, the device insulating layer 28 remains and terminates immediately from a region where a movable electrode contact 35 to be described below is located beyond the second IJ 24 along the Y direction from the anchor 21.

The device wiring 30 includes a fixed electrode wiring 31 connected to the fixed electrode 23, and a movable electrode wiring 34 connected to the movable electrode 27, wherein the fixed electrode wiring 31 and the movable electrode wiring 34 are individually laminated on the Z2 side of the device insulating layer 28.

The device wiring 30 is made of a material having a wettability with respect to the bonding layer 4 and does not cause any eutectic diffusion in the bonding layer 4. In this embodiment, the bonding layer 4 is made of an aluminum germanium eutectic material (to be referred to as an AlGe alloy) 90, so the device wiring 30 adopts polysilicon with conductivity as a material having a wettability with respect to the AlGe alloy 90 and not causing any eutectic diffusion in the AlGe alloy 90.

In addition to being made of polysilicon with conductivity, the device wiring 30 can further be made of a conductive material selected from a group including polycide alloy, titanium nitride alloy, and titanium tungsten alloy. These materials similarly have a wettability with respect to the AlGe alloy 90, and do not cause any eutectic diffusion in the AlGe alloy.

The fixed electrode wiring 31 includes: the fixed electrode contact 32, penetrating the device insulating layer 28 along the Z direction when viewed from the Z2 side, and electrically coupled to the fixed electrode 23; a fixed electrode bonding portion 33, located on the anchor 21; and a wiring portion 31a, extending from the fixed electrode contact 32 across the first IJ 22 toward the X1 side to the fixed electrode bonding portion 33. The fixed electrode bonding portion 33 is configured as a portion of the fixed electrode wiring 31, and at the same time serves as a bonding portion of the cap wafer 3.

The movable electrode wiring 34 includes: the movable electrode contact 35, penetrating the device insulating layer 28 along the Z direction when viewed from the Z2 side, and electrically coupled to the movable electrode 27 (located at the base end 25a of the spring 25 on the Y2 side in this embodiment); a movable electrode bonding portion 36, located on the anchor 21; and a wiring portion 34a, extending from the movable electrode contact 35 across the second IJ 24 toward the Y1 side to the movable electrode bonding portion 36. The movable electrode bonding portion 36 is configured as a portion of the movable electrode wiring 34, and at the same time serves as a bonding portion with respect to the cap wafer 3.

In this embodiment, with the presence of the pair of fixed electrode 23 and one movable electrode 27, there are two fixed electrode wirings 31 and one movable electrode wiring 34. Thus, the two fixed electrode bonding portions 33 and the one movable electrode bonding portion 36 are correspondingly located on the Z2 side of the anchor 21.

Moreover, a device peripheral bonding layer 40 extending along an outer periphery of the cavity 13 when viewed from the Z2 side is further laminated on the Z2 side of the device insulating layer 28. The device peripheral bonding layer 40 is laminated on the device insulating layer 28, that is, laminated on the same layer as the device wiring 30, is made of a same material as the device wiring 30 and is conductive. The device peripheral bonding layer 40 further includes a device peripheral contact 41 penetrating the device insulating layer 28 along the Z direction and electrically coupling the device peripheral bonding layer 40 to the device substrate 10.

### [Cap Wafer]

Next, the cap wafer 3 is described with reference to FIG. 2 and FIG. 4 below. FIG. 4 shows a plan view obtained by viewing the cap wafer 3 from the Z1 side. First of all, referring to FIG. 2, the cap wafer 3 includes: a cap substrate 50; a first cap insulating layer 53, laminated on the Z1 side of the cap substrate 50; a cap wiring 60, laminated on the Z1 side of the first cap insulating layer 53; a second cap insulating layer 54, laminated on the Z1 side, and between which and the first cap insulating layer 53 the cap wiring 60 is interposed; and a bonding electrode 55, laminated on the Z1 side of the second cap insulating layer 54.

The cap substrate 50 includes: a first main surface 51, located on the Z1 side and extending in parallel to the X direction and the Y direction; and a second main surface 52, located on a side opposite to the first main side 51, that is, the Z2 side, and extending in parallel to the X direction and the Y direction. The cap substrate 50 is made of silicon doped with high-concentration p-type impurities or n-type impurities, and is conductive.

In the plan view shown in FIG. 1, the cap substrate 50 is larger than the device substrate 10. In this embodiment, the cap substrate 50 is larger than the device substrate 10 on the X1 side. On a portion of the cap wafer 3 that is not covered by the device substrate 10, a plurality of electrode pads 50 which input and output electrical signals from and to an external device (for example, an application-specific integrated circuit (ASIC)) of the MEMS device 1 are provided.

As shown in FIG. 2, the cap substrate 50 includes a stopper 50a facing the mass 26 and the movable electrode 27 of the device wafer 2 from the Z2 side, and a groove 50b recessed toward the Z2 side around the stopper 50a. The stopper 50a functions as a stopper that abuts against the mass 26 and the movable electrode 27 when they move excessively toward the Z2 side, hence suppressing the mass 26 and the movable electrode 27 from moving excessively toward the Z2 side.

Moreover, surfaces of the stopper 50a and the groove 50b not laminated with the first cap insulating layer 53 and not laminated with the second cap insulating layer 54 become exposed from a surface of the device substrate 10, and no charge is produced even if the mass 26 and the movable electrode 27 come into contact with the stopper 50a. Accordingly, the mass 26 and the movable electrode 27 are prevented from attaching to the stopper 50a due to a static electricity.

The first cap insulating layer 53 is laminated on a portion of the Z1 side of the cap substrate 50, except for the stopper 50a and the groove 50b. The first cap insulating layer 53 is made of SiO and is an insulator.

As shown in FIG. 4, the cap wiring 60 includes first to third cap wirings 61 to 63. The first to third cap wirings 61 to 63 extend from one end positioned corresponding to the two fixed electrode bonding portions 33 and the one movable electrode bonding portion 36 of the device wafer 2 along the Z direction to an outer side of the cavity 13, and are connected to first to third electrode pads 57A to 57C. Furthermore, the cap wiring 60 includes a fourth cap wiring 64. The fourth cap wiring 64 is connected to a corresponding fourth electrode pad 57D from one end positioned corresponding to a cap peripheral bonding layer 70 to be described below along the Z direction. A fifth cap wiring 65 connecting the third electrode pad 57C and the fourth electrode pad 57D is further included.

The first to third cap wirings 61 to 63 are electrically coupled to the corresponding cap wiring 55 via a bonding electrode contact 56 penetrating the second cap insulating layer 54 along the Z direction. The fourth cap wiring 64 is electrically coupled to the cap substrate 50 via a cap wiring contact 58 penetrating the first cap insulating layer 53 along the Z direction, and is electrically coupled to the cap peripheral bonding layer 70 via a cap peripheral contact 71 penetrating the second cap insulating layer 54 along the Z direction.

The individual cap wirings 60 and the individual electrode pads 57 are laminated on the first cap insulating layer 53, that is, laminated on the same layer and are made of the same material. In this embodiment, the cap wirings 60 and the electrode pads 57 are three-layer structures including a titanium nitride (TiN) layer laminated on the first cap insulating layer 53, an aluminum copper (AlCu) layer laminated on the Z1 side, and a TiN layer laminated on the Z1 side, and are conductive. The bonding electrode contact 56 and the cap wiring contact 58 are formed by surrounding tungsten (W) by TiN, and are conductive.

The second cap insulating layer 54 is laminated on the Z1 side of the first cap insulating layer 53, between which and the first cap insulating layer 53 the cap wiring 60 is interposed. The second cap insulating layer 54 is made of SiO and is an insulator. The second cap insulating layer 54 is not laminated on a portion positioned corresponding to the plurality of electrode pads 57. Accordingly, the plurality of electrode pads 57 are exposed from the Z1 side from the cap wafer 3.

On the Z1 side of the second cap insulating layer 54, the bonding electrode 55 is positioned to face the fixed electrode bonding portion 33 and the movable electrode bonding portion 36 of the device wafer 2 from the Z2 side. That is, in this embodiment, the bonding electrode 55 is provided as three in total, including those positioned to face the two fixed electrode bonding portions 33 and that positioned to face the one movable electrode bonding portion 36. The bonding electrodes 55 are respectively electrically coupled to the corresponding cap wirings 60 via the bonding electrode contact 56 penetrating the second cap insulating layer 54 along the Z direction.

The bonding electrodes 55 are made of TiN and are conductive. The bonding electrodes 55 function as a barrier layer to prevent eutectic diffusion of eutectic reactions of Al and Ge in the bonding layer 4 described below to the Z2 side.

In addition, on the Z1 side of the second cap insulating layer 54, the cap peripheral bonding layer 70 is laminated and positioned corresponding to the device peripheral bonding layer 40 along the Z direction. The cap peripheral bonding layer 70 is laminated on the second cap insulating layer 54, that is, laminated on the same layer as the bonding electrode 55, is made of a same material as the bonding electrode 55 and is conductive.

### [Bonding Layer]

Next, the bonding layer 4 is described with reference to FIG. 1 and FIG. 2 below. As shown in FIG. 1 and FIG. 2, the bonding layer 4 includes: an outer peripheral bonding layer 5, extending along the device peripheral bonding layer 40 and the cap peripheral bonding layer 70, and bonding the two along the Z direction; and an inner bonding layer 6, located between the two fixed electrode bonding portions 33, the one movable electrode bonding portion 36 and the three bonding electrodes 55, and individually bonding all of them along the Z direction.

The bonding layer 4 is an AlGe alloy produced by an eutectic reaction of Al and Ge. With the outer peripheral bonding layer 5, the sensor unit 20 is sealed in a space blocked from the outside between the device wafer 2 and the cap wafer 3. With the inner peripheral bonding layer 6, the device wiring 30 of the device wafer 2 is electrically coupled to the cap wiring 60 of the cap wafer 3. That is, with the bonding layer 4, the device wafer 2 and the cap wafer 3 can be bonded along the Z direction, and the device wirings 30 and the cap wirings 60 can be electrically coupled.

### [Method for Manufacturing MEMS Device]

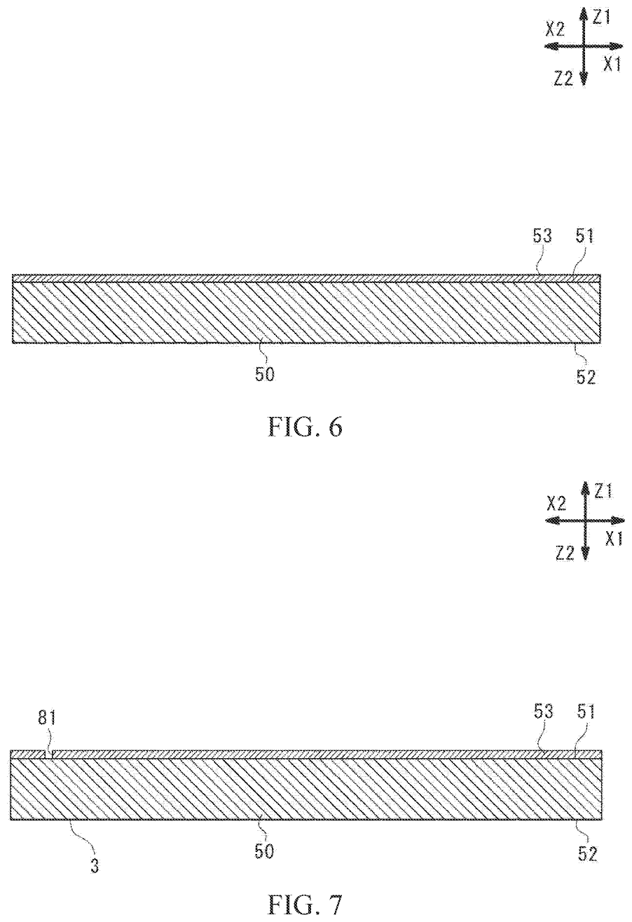

Next, details of a method for manufacturing the MEMS device 1 are given with reference to FIG. 6 to FIG. 22 below.

### (Processes for Forming Cap Wafer)

First of all, referring to FIG. 6 to FIG. 12, processes for forming the cap wafer 3 are described. As shown in FIG. 6, the cap substrate 50, that is, a conductive silicon substrate doped with high-concentration p-type impurities or n-type impurities, is prepared. The first cap insulating layer 53, that is, SiO, is formed on the first main surface 51 of the cap substrate 50 by thermal oxidizing the first main surface 51.

Next, as shown in FIG. 7, using a generally known patterning technique, a partially open through via 81 corresponding to the cap wiring contact 58 is formed by partially removing the first cap insulating layer 53 by etching.

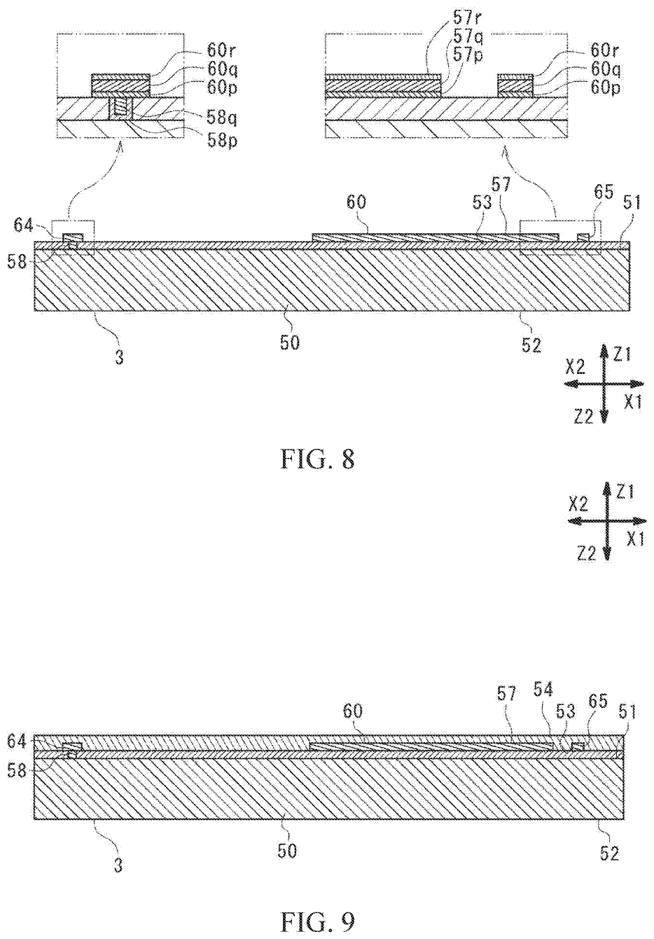

Next, as shown in FIG. 8, the cap wiring contact 58 is formed in the through via 81. More specifically, referring to the enlarged diagram on the left of FIG. 8, a TiN layer 58p is first laminated in a recessed manner along an inner wall and a bottom wall of the through via 81, tungsten (W) 58q is laminated on the recess of the TiN layer 58p, and then the surface is flattened using such as chemical mechanical polishing (CMP), accordingly forming the cap wiring contact 58 in the through via 81.

Next, using a generally known patterning technique, the cap wiring 60 and the electrode pad 57 are laminated on the first cap insulating layer 53. More specifically, TiN layers 60p and 57p are first laminated, AlCu layers 60q and 57q are then laminated, and TiN layers 60r and 57r are further laminated. That is, the cap wiring 60 and the electrode pad 70 are three-layer structures formed as TiN/AlCu/TiN.

Next, as shown in FIG. 9, the second cap insulating layer 54 is laminated on the Z1 side of the first cap insulating layer 53, the cap wiring 60 and the electrode pad 57. The second cap insulating layer 54 is formed by such as chemical vapor deposition (CVD) using tetra ethoxy silane (TEOS) as a material. The second cap insulating layer 54 is configured as a passivation layer of the cap wiring 60. Flattening is performed by such as CMP after the second cap insulating layer 54 is laminated.

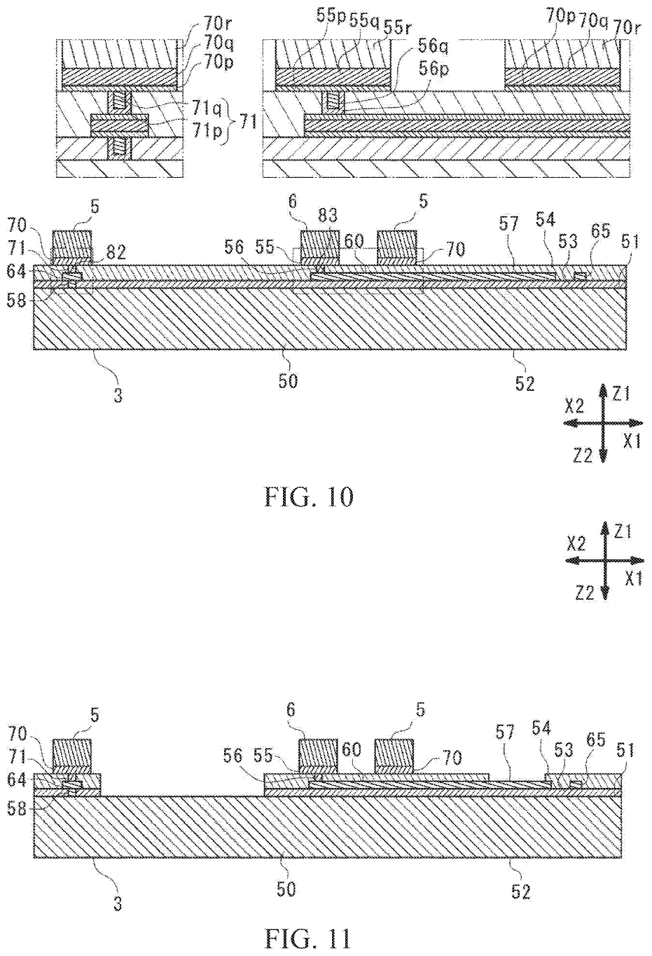

Next, as shown in FIG. 10, using a generally known patterning technique, partially open through vias 82 and 83 corresponding to the cap peripheral contact 71 and the bonding electrode contact 56 are formed by etching the second cap insulating layer 54.

Next, the cap peripheral contact 71 and the bonding electrode contact 56 are formed in the vias 82 and 83. More specifically, the cap peripheral contact 71 and the bonding electrode contact 56 are formed by a same means as the cap wiring contact 58 above, and include recessed TiN layers 71p and 56p along inner walls of the vias 82 and 83, and W 71q and 56q formed on the recess of the TiN layers 71p and 56p.

Next, using a generally known patterning technique, the bonding electrode 55 and the cap peripheral bonding layer 70 are formed on the second cap insulating layer 54. More specifically, TiN layers 55p and 70p are first laminated, and AlCu layers 55q and 70q are then laminated. Next, Ge layers 55r and 70r are laminated on the Z1 side of the AlCu layers 55q and 70q. The Ge layers 55r and 70r undergo an eutectic reaction with the AlCu layers 55q and 70q to become an AlGe alloy, thereby forming the bonding layer 4.

Next, as shown in FIG. 11, the cap substrate 50 is exposed by removing portions of the first cap insulating layer 53 and the second cap insulating layer 54 facing the mass 26 and the movable electrode 27 of the sensor unit 20 along the Z direction by etching. Furthermore, the electrode pad 57 is exposed by removing a region of the second cap insulating layer 54 covering the electrode pad 57 by etching.

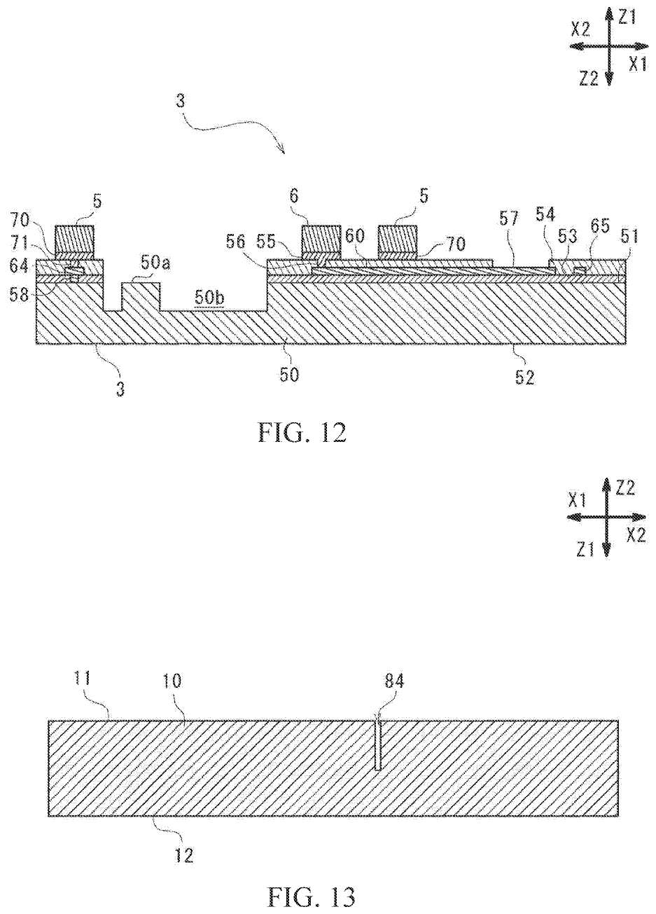

Next, as shown in FIG. 12, a groove 50b recessed toward the Z2 side is formed to have the portion exposed from the cap substrate 50 to remain as the stopper 50a with respect to the mass 26 and the movable electrode 27. Accordingly, the cap wafer 3 is completed.

### (Processes for Forming Device Wafer)

Next, referring to FIG. 13 to FIG. 17, processes for forming the device wafer 2 are described. As shown in FIG. 13, the device substrate 10, that is, a conductive silicon substrate doped with high-concentration p-type impurities or n-type impurities, is prepared.

Next, a trench 84 is formed by performing deep etching on the device substrate 10 toward the Z1 side by anisotropic etching using a mask positioned corresponding to the first IJ 22 and the second IJ 24, wherein the mask is formed by patterning a thermal oxidation film obtained by thermal oxidizing the first main surface 11 of the device substrate 10, although omitted from the drawings. The mask is removed after the trench 84 is formed.

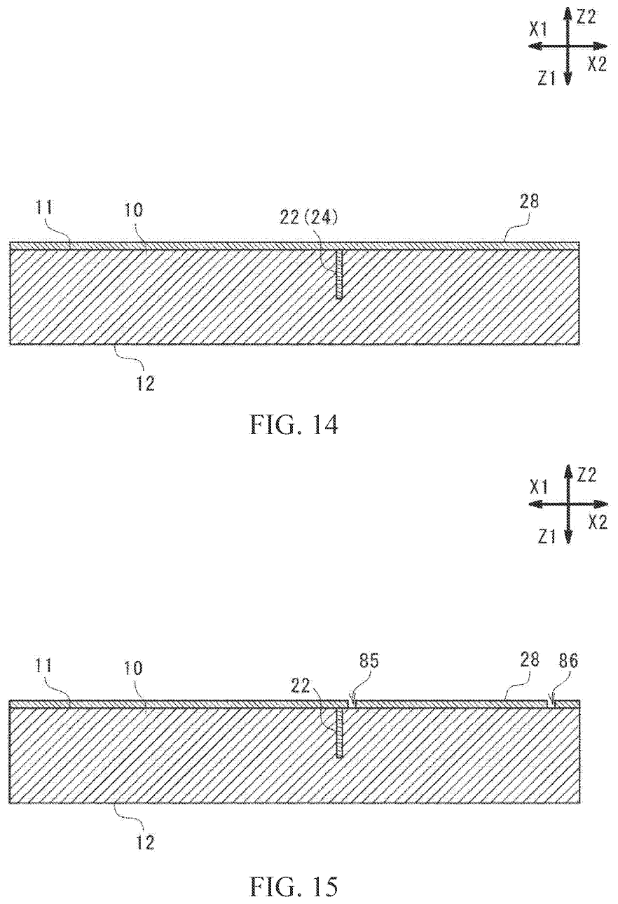

Next, as shown in FIG. 14, the first IJ 22 and the second IJ 24 including SiO formed by thermal oxidizing an inner wall of the trench 84 are formed by thermal oxidizing the inner wall of the trench 84. Next, the device insulating layer 28 is formed by laminating SiO on the first main surface 11 of the device substrate 10.

Next, as shown in FIG. 15, using a generally known patterning technique, partially open through vias 85 and 86 corresponding to the fixed electrode contact 32 and the device peripheral contact 41 are formed by partially removing the device insulating layer 28 by etching. Although omitted from the drawings, a through via is also formed at a portion in the device insulating layer 28 corresponding to the movable electrode contact 35.

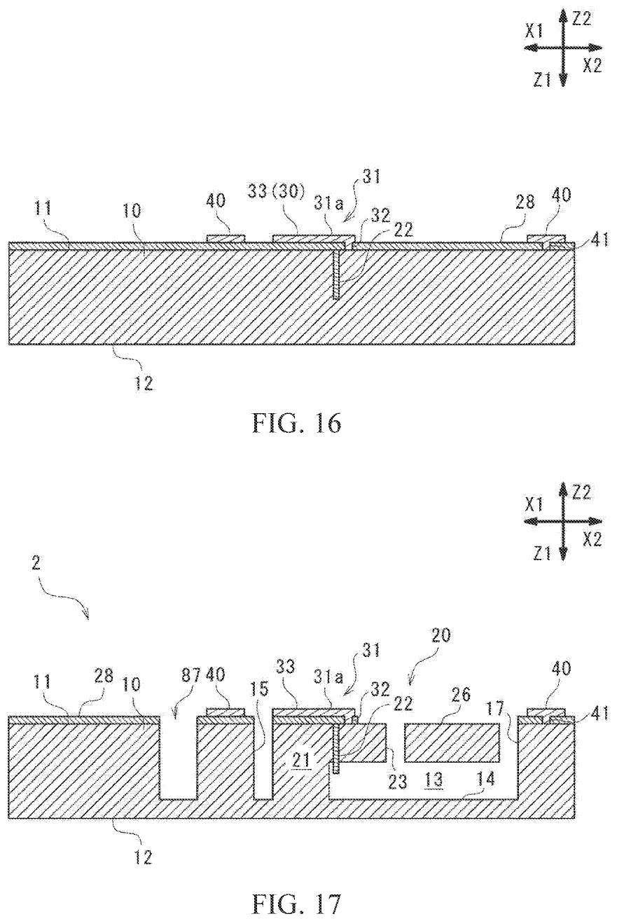

Next, as shown in FIG. 16, using a generally known patterning technique, the device wiring 30 and the device peripheral bonding layer 40 are laminated on the Z2 side of the device insulating layer 28. At this point, the fixed electrode contact 32, the movable electrode contact 35 and the device peripheral contact 41 are also formed. The device wiring 30 and the device peripheral bonding layer 40 are polysilicon doped with high-concentration p-type impurities or n-type impurities, and are laminated by such as low-voltage CVD. Although omitted from the drawings, a passivation layer, for example, SiO, is laminated on the device wiring 30 and the device peripheral bonding layer 40.

Next, as shown in FIG. 17, the sensor unit 20 is formed by a generally known etching technique. The device substrate 10 is exposed by removing portions from the device insulating layer 28 and the passivation layer by etching, except for a region defined as the cavity 13 and a portion shaped consistent with the sensor unit 20, although omitted from the drawings.

Next, by using the device insulating layer 28 and the passivation layer as a mask, a trench along the shapes of the sensor unit 20 and the cavity 13 is accordingly formed by deep etching the device substrate 10 using anisotropic etching toward the Z1 side.

Next, an oxide film is deposited on an inner wall of the trench. Next, an oxide film on a bottom wall of the trench is removed by etching. Next, the cavity 13 is formed by removing the bottom of the trench by isotropic etching, and the sensor unit 20 is at the same time formed. The sensor unit 20 is supported inside the cavity 13 by the anchor 21 and a portion other than the anchor 21 is released from the bottom wall 14 of the cavity 13 and spaced apart from the Z2 side.

Lastly, the SiO on a sidewall of the trench is removed by HP vapor phase etching, the device insulating layer 28 on the fixed electrode 23, the movable electrode 27, the spring 25 and the mass 26 of the sensor unit 20 is also removed, and the passivation layer is further removed. Accordingly, the device wafer 2 is completed.

Moreover, the device wafer 2 is closer to the X1 side than the sensor unit 20, is formed to be closer to the X2 side than the electrode pad 57 of the cap wafer 3, and is formed on a trench 87 extending along the Y direction and recessed toward the Z1 side. The trench 87 and the sensor unit 20 are formed at the same time.

### (Processes for Bonding Device Wafer and Cap Wafer)

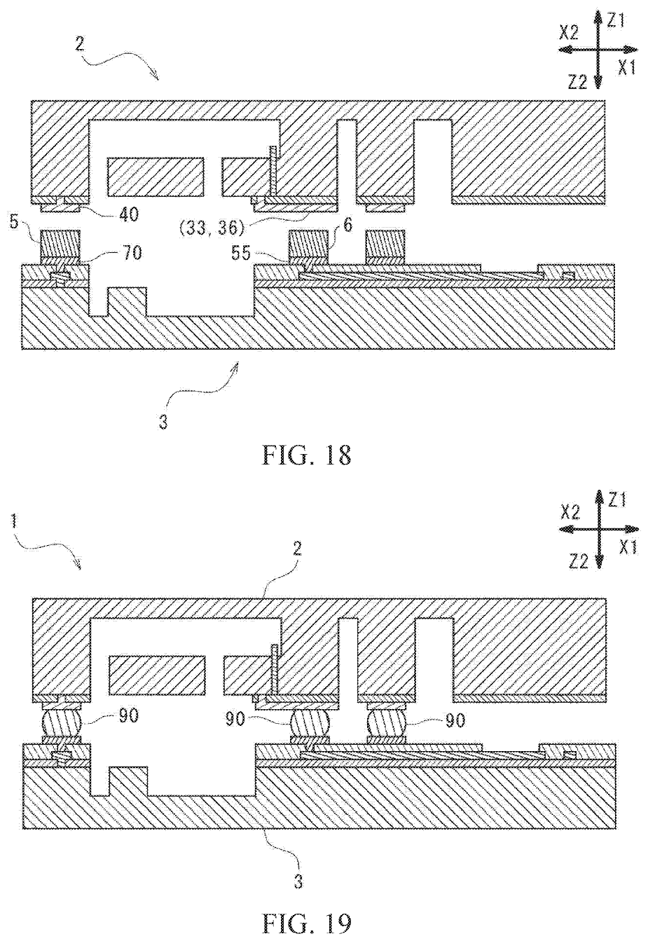

Next, referring to FIG. 18 to FIG. 22, processes for bonding the device wafer 2 and the cap wafer 3 to manufacture the MEMS device 1 are described below. As shown in FIG. 18, the device wafer 2 is inverted by 180° to face the cap wafer 3 along the Z direction. At this point, the positions of the device wafer 2 along the X direction and the Y direction are adjusted, and alignment is performed to have the two fixed electrode bonding portions 33, the one movable electrode bonding portion 36 and the device peripheral bonding layer 40 to respectively face the three bonding electrodes 55 of the cap wafer 3 and the cap peripheral bonding layer 70 along the Z direction.

Next, as shown in FIG. 19, while abutting the two fixed electrode bonding portions 33, the one movable electrode bonding portion 36 and the device peripheral bonding portion 40 against the three bonding electrodes 55 of the cap wafer 3 and the cap peripheral bonding layer 70, the device wafer 2 and the cap wafer 3 are pressurized at a high temperature.

In this embodiment, since the bonding layer 4 are made of the aluminum geranium eutectic material 90 (to be referred to as an AlGe alloy below) formed by an eutectic reaction of the AlCu layers 55q and 70q and the Ge layers 55r and 70r, the two wafers are kept abutting against each other with a force of several kN (for example, between about 1 kN and about 100 kN) per wafer at a temperature of more than 423° C. (for example, between about 430° C. and about 500° C.), which is an eutectic temperature of Al and Ge.

At this point, the AlGe alloy 90 and the device wiring 30 and the device peripheral bonding layer 40 made of polysilicon in the device wafer 2 undergo a three-phase eutectic reaction and become bonded. However, due to an increase in a concentric point (for example, more than about 500° C.) of the three-phase eutectic reaction, the eutectic reaction of the AlGe alloy 90 is stopped so as to prevent from diffusion toward the side of the device wiring 30 and the device peripheral bonding layer 40.

On the other hand, on the side of the cap wafer 3, the AlGe alloy 90 stops diffusing toward the side of lower layers due to the TiN layers 55p and 70p functioning as a barrier layer. Then, the temperature is reduced to stop the eutectic reaction and to harden the AlGe alloy 90, accordingly completing bonding of the device wafer 2 and the cap wafer 3.

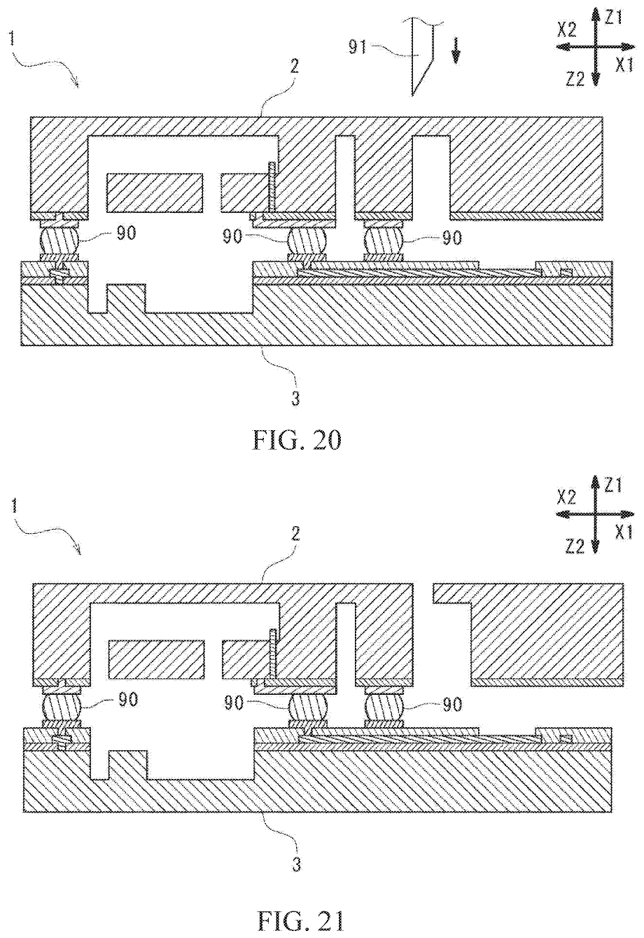

Next, as shown in FIG. 20, a cutting blade 91 positioned in alignment with the trench 87 is caused to descend toward the Z2 side. As a result, as shown in FIG. 21, by cutting and separating a portion in the device wafer 2 located closer to the X1 side than the trench 87, the electrode pad 57 of the cap wafer 3 is exposed from the Z1 side. Accordingly, the MEMS device 1 is completed.

The following effects are achieved according to the MEMS device 1 given in the description.

(1) A MEMS device 1 includes a device wafer 2, a cap wafer 3 and a bonding layer 4, wherein the device wafer 2 includes: a device substrate 10, having a first main surface 11, a second main surface 12 opposite to the first main surface 11, and a cavity 13 recessed from the first main surface 11 toward a Z1 side of the second main surface 12; a sensor unit 20, located within the cavity 13 and mechanically connected to and electrically insulated from the device substrate 10 by a single anchor 21; and a device wiring 30, electrically coupled to the sensor unit 20.

The cap wafer 3 includes: a cap substrate 50, facing the device wafer 2 from a side of the first main surface 11; and a cap wiring 60, electrically coupled to the device wiring 30.

The bonding layer 4 bonds the device wafer 2 with the cap wafer 3.

The device wiring 30 is directly connected to the bonding layer 4 and is electrically coupled to the cap wiring 60 via the bonding layer 4.

As a result, with the sensor unit 20 mechanically connected to the single anchor 21, an input path of strain transmitted from the outside to the sensor unit 20 is single as well. Thus, since influences of the strain transmitted from the outside are uniformly distributed on the sensor unit 20, detection characteristics of the sensor unit 20 can be better stabilized to thereby suppress a zero point offset.

Moreover, as the device wiring 30 is directly bonded at the boding layer 4, it is not necessary to separately provide bonding portions on the device wafer 2 and the device wiring 30, hence simplifying a structure of the device wafer 2. As a result, forming processes of the device wafer 2 can be readily simplified because the number of layers of the device wafer 2 is decreased, and the sensor unit 20 to be formed on the device substrate 10 can be better formed with good precision. Thus, a deviation in the shape of the sensor unit 20 is suppressed, accordingly suppressing the zero point offset caused by the deviation.

In contrast, when a sensor unit is connected to multiple anchors, strain from the outside is input to the sensor unit via multiple input paths, in a way that influences of the strain are non-uniformly applied to the sensor unit. Thus, non-uniform strain is likely produced at the sensor unit, and this can easily deviate detection characteristics of the sensor unit. Moreover, when bonding portions are separately provided on a device wafer and a device wiring, the number of layers of the device wafer is increased, so forming processes of the device wafer can become complicated and deviation in the shape of the sensor unit can be easily incurred. That is to say, as in a sensor unit in a conventional structure, when the sensor unit has multiple anchors and/or a device wafer has a bonding portion located on a layer different from the device wiring, it can be challenging to suppress a zero point offset.

(2) The sensor unit 20 includes: the anchor 21, fixed to a wall of the cavity 13;

a fixed electrode 23, mechanically connected to the anchor 21 via a first isolation joint 22, electrically insulated, and extending along an X direction; a spring 25, mechanically connected to the anchor 21 via a second isolation joint 24 and electrically insulated; a mass 26, mechanically connected and electrically coupled to the spring 25; a movable electrode 27, mechanically connected and electrically coupled to the mass 26, extending along the X direction, and facing the fixed electrode 23 along a Y direction; and a device insulating layer 28, disposed on at least a region of a proximal side of the first isolation joint 22 in the anchor 21 and the fixed electrode 23, disposed on at least a region spanning the spring 25, the mass 26 and the movable electrode 27, and located on a proximal side of the second isolation joint 24, and laminated on the side of the first main surface 11, a portion of the sensor unit 20 other than the anchor 21 is spaced apart from a bottom surface 14 of the cavity 13 toward a Z2 side. The device wiring 30 includes: a fixed electrode wiring 31, laminated on the device insulating layer 28, and extending from a fixed electrode contact 32 across the first isolation joint 22 to a fixed electrode bonding portion 33, the fixed electrode contact 32 positioned corresponding to the fixed electrode 23 when viewed from the side of the first main surface 11, and electrically coupled to the fixed electrode 23 through the device insulating layer 28; and a movable electrode wiring 34, laminated on the device insulating layer 28, and extending from a movable electrode contact 35 across the second isolation joint 24 to a movable electrode bonding portion 36, the movable electrode contact 35 positioned corresponding to the spring 25, the mass 26 or the movable electrode 27 when viewed from the side of the first main surface 11, and electrically coupled to the spring 25, the mass 26 or the movable electrode 27 through the device insulating layer 28. The device wiring 30 is bonded to the cap wiring 60 via the bonding layer 4 at the fixed electrode bonding portion 33 and the movable electrode bonding portion 36, and the device wiring 30 is electrically coupled to the cap wiring 60.

As a result, with the vertical separation extending upward along the Z direction of the isolation joints, a structure in which the fixed electrode 23 and the movable electrode 27 are mechanically connected to and electrically insulated from the single anchor 21 can be implemented. Thus, influences caused by strain transmitted from the outside to the fixed electrode 23 and the movable electrode 27 can be kept uniform; in other words, both of the fixed electrode 23 and the movable electrode 27 receive similar influences from the strain while being kept at their relative positions, so characteristics of the sensor unit 20 including the electrodes can be better stabilized.

As such, since the device wafer 2 also serves as a bonding portion bonding the device wiring 30 to the bonding layer 4, it is not necessary for the device wafer 2 to be separately provided with a wiring layer and a bonding portion. As a result, as the number of lamination processes is reduced compared to a case where the device wafer 2 has more layers, it is easier to form the fixed electrode 23 and the movable electrode 27 with better precision. In this case, for example, a manufacturing error in a distance between the fixed electrode 23 and the movable electrode 27 is suppressed, so an offset at a zero point at which no external force is generated can be more readily reduced.

Thus, regardless of conditions of the strain transmitted from the outside, output characteristics of the sensor unit 20 can be kept uniform and detection accuracy can be further improved.

(3) The cap wafer 3 further includes: a first cap insulating layer 53, laminated on the cap substrate 50; a second cap insulating layer 54, between which and the first cap insulating layer 53 the cap wiring 60 is laminated; and a bonding electrode 55, laminated on the second cap insulating layer 54 and is electrically coupled to the cap wiring 60 via a bonding electrode contact 56 penetrating the second cap insulating layer 54.

The cap wafer 3 is bonded to the fixed electrode bonding portion 33 and the movable electrode bonding portion 36 via the bonding layer 4 at the bonding electrode 55.

As a result, the cap wiring 60 and the bonding electrode 55 are formed on the side of the cap wafer 3.

(4) The fixed electrode bonding portion 33 and/or the movable electrode bonding portion 36 can also be positioned corresponding to the anchor 21 when viewed from the Z direction.

As a result, the device wiring 30 can be formed to be shorter, and it is not necessary to additionally form portions supporting the fixed electrode bonding portion 33 and the movable electrode bonding portions 36.

(5) The cap wafer 3 can further include an electrode pad 57 to which an external wiring is connectable, and the electrode pad 57 is electrically coupled to an end of the cap wiring 60 opposite to the bonding electrode 55.

As a result, since the device wafer 2 does not include the electrode pad 57, the device wafer 2 can be more readily simplified. Accordingly, as described above, the increase in the number of layers of the device wafer 2 can be suppressed, and the sensor unit 20 can be better formed with good precision.

(6) The electrode pad 57 and the cap wiring 60 can be located on same layer as the cap wafer 3 and are made of same material.

As a result, the electrode pad 57 and the cap wiring 60 can be laminated by the same process.

(7) The bonding layer can be made of aluminum germanium alloy 90.

As a result, the device wiring 30 of the device wafer 2 can be electrically coupled and bonded to the bonding electrode 55 of the cap wafer 3.

(8) The device wiring 30 can also be made of a material having a wettability with respect to the bonding layer 4 and does not cause any eutectic diffusion.

As a result, while bonding the device wiring 30 with the bonding layer 4, the device wiring 30 is suppressed from being introduced into the bonding layer 4 due to eutecticization, thereby suppressing the device wiring 30 from disappearing.

(9) The device wiring 30 can further be made of a conductive material selected from a group comprising polysilicon, polycide alloy, titanium nitride alloy, and titanium tungsten alloy.

As a result, the device wiring 30 is conductive and ensures the bonding ability with the bonding layer 4.

(10) The bonding electrode can be further made of aluminum alloy.

(11) The anchor 21 can further extend along the Z direction from a bottom wall 14 of the cavity 13.

As a result, the degree of freedom of a configuration position of the anchor 21 within the cavity 13 can be easily increased.

(12) The anchor 21 can further be fixed to a first vertical wall 15 of the cavity 13, extend along the X direction, and is spaced apart from a bottom wall 14 of the cavity 13 toward the Z2 side.

As a result, the anchor 21 can be more readily formed by using the first vertical wall 15 of the cavity 13.

(13) The device wafer 2 can further include a device peripheral bonding layer 40 around the cavity 13, and the cap wafer 3 includes a cap peripheral bonding layer 70 bonded to the device peripheral bonding layer 40 via the bonding layer 4.

As a result, by bonding the device peripheral bonding layer 40 to the cap peripheral bonding layer 70, the sensor unit 20 can be easily sealed on the inside of the MEMS device 1.

(14) The device peripheral bonding layer 40 can further be located on same layer as the device wiring 30 of the device wafer 2 and be made of a material same as a material of the device wiring 30.

As a result, the device peripheral bonding layer 40 and the device wiring 30 can be laminated by the same process.

(15) The cap peripheral bonding layer 70 can further be located on same layer as the bonding electrode 55 of the cap wafer 3 and is made of a material same as a material of the bonding electrode 55.

As a result, the cap peripheral bonding layer 70 and the bonding electrode 55 can be laminated by the same process.

(16) The device peripheral bonding layer 40 and the cap periphery bonding layer 70 can further be electrically connectable via the bonding layer 4.

As a result, the device peripheral bonding layer 40 and the cap periphery bonding layer 70 can be set to the same potential.

(17) The cap wafer 3 can further include: a fourth peripheral bonding wiring 64, electrically coupled to the cap peripheral bonding layer 70; and an electrode pad 57, connected to the fourth peripheral bonding wiring 64 and to which an external wiring is connectable.

As a result, by connecting an external wiring to the electrode pad 57 and applying a voltage or connecting it to a ground potential, the device peripheral bonding layer 40 and the cap periphery bonding layer 70 can be set to the same potential.

(18) The device peripheral bonding layer 40 can further be electrically coupled to the device substrate 10 via a device peripheral contact 41 penetrating the device insulating layer 28, and the cap periphery bonding layer 70 is electrically coupled to the cap substrate 50 via a cap peripheral contact 71 penetrating the first cap insulating layer 53.

As a result, the device substrate 10 to the cap substrate 50 can be set to the same potential. Accordingly, for example, by surrounding the sensor unit 20 by the device substrate 10 and the cap substrate 50 set to the same potential, electromagnetic shielding for the sensor unit 20 can be formed.

(19) A method for manufacturing a MEMS device 1 comprises: forming a device wafer 2 including: a device substrate 10, having a first main surface 11, a second main surface 12 opposite to the first main surface 11, and a cavity 13 recessed from the first main surface 11 to a Z1 side of the second main surface 12; a sensor unit 20, located within the cavity 13 and mechanically connected to and electrically insulated from the device substrate 10 by a single anchor 21; and a device wiring 30, electrically coupled to the sensor unit 20; forming a cap wafer 3 including: a cap substrate 50, facing the device wafer 2 from a side of the first main surface 11; and a cap wiring 60, electrically coupled to the device wiring 30; and bonding the device wafer 2 and the cap wafer 3 via a bonding layer 4. In the bonding, the device wiring 30 is directly connected to the bonding layer 4 and is electrically coupled to the cap wiring 60 via the bonding layer 4.

Moreover, the present disclosure is not limited to the embodiments described above, and various modification can be made thereto.

In the embodiments, the sensor unit 20 is formed from the device substrate 10 by etching; however, the present disclosure is not limited to such example. For example, in the cross-sectional diagram of a device wafer 105 along the X-Y plane in FIG. 22, the device wafer 105 is configured as a silicon-on-insulator (SOI) substrate 100 in substitution for the configuration of the device substrate 10.

For example, the SOI substrate 100 is formed by a first layer 101 located on the Z2 side, a second layer 102 laminated on the Z1 side and a third layer 103 laminated closer to the Z1 side, wherein the first layer 101 and the third layer 103 are made of silicon with conductivity, and the second layer 102 is made of an insulating layer of SiO. By deep etching a trench extending toward the Z1 side and reaching the second layer 102 in the first layer 101 and partially removing the second layer 102 using an HF vapor, a sensor unit 120 including an anchor 121 supported by the second layer 102, and a fixed electrode 123 and a movable electrode extending horizontally from the anchor 121 and spaced apart from a bottom wall 114 of a cavity 113 toward the Z2 side can be formed.

In addition, in the fixed electrode 123 and the movable electrode, in order to form mechanical connection with and electrical isolation from the anchor 121, the first layer 101 is deep etched toward the Z1 side and a trench reaching the second layer 102 is deep etched, and polysilicon as an insulator is filled in the trench to form a deep trench isolation (DTI) 122. With the DTI 122, a vertically separated structure extending along the Z direction between the anchor 121, the fixed electrode 123 and the movable electrode can be implemented. Thus, a device wafer 105 including the sensor unit 120 supported by the single anchor 121 can be formed from the SOI substrate 100.

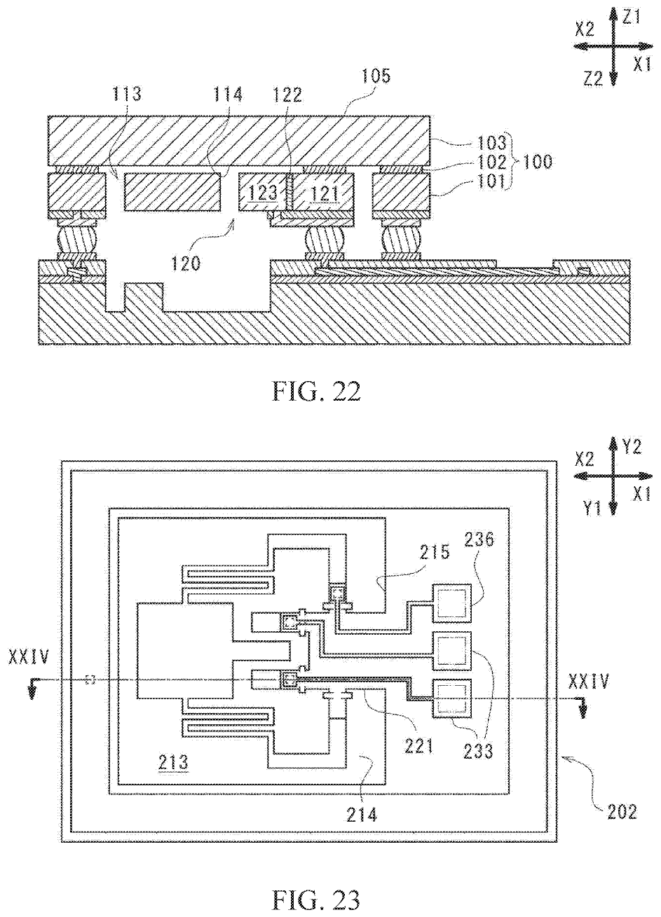

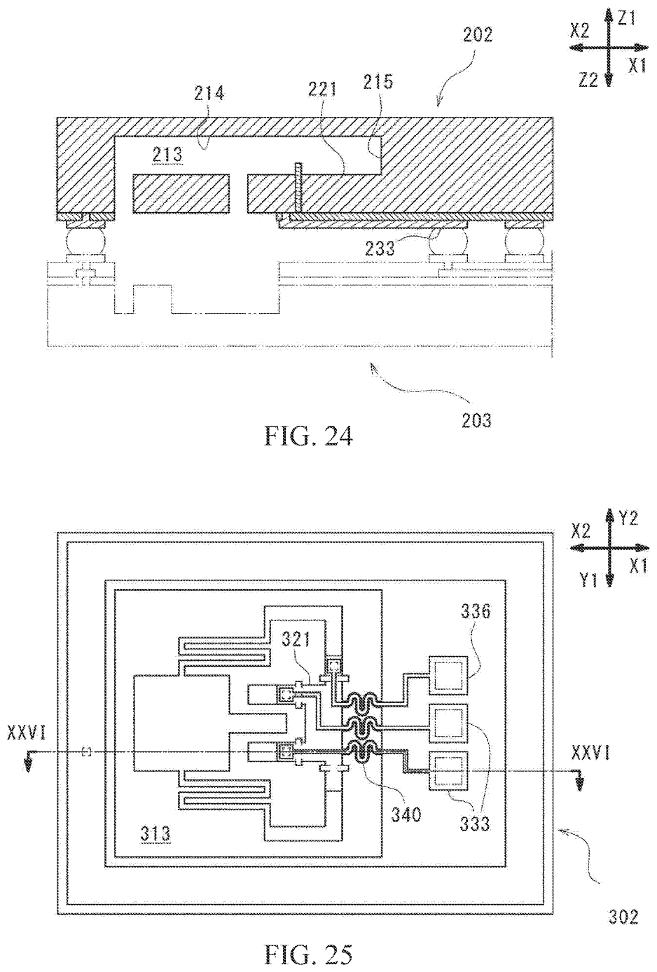

Moreover, in this embodiment, the anchor 21 is configured to extend from the bottom wall 14 of the cavity 13 along the Z direction; however, the present disclosure is not limited to such example. For example, FIG. 23 shows a bottom view of a device wafer 202 of another variation example, and FIG. 24 shows a cross-sectional diagram of the device wafer 202 in an X-Z plane along the line XXIV-XXIV in FIG. 23. Moreover, a cap wafer 203 corresponding to the device wafer 202 is indicated by a double-dot dashed line in FIG. 24 for reference. As shown in FIG. 23 and FIG. 24, an anchor 221 can also be configured to extend from a first vertical wall 215 located on the X1 side of a cavity 213 toward the X2 side and be spaced apart from a bottom wall 214 of the cavity 213 toward the Z1 side.

In this case, a device wiring 230 can also be formed to extend across the anchor 221, and a fixed electrode bonding portion 233 and a movable electrode bonding portion 236 are located, for example, on an outer side of the cavity 213 when viewed from the Z direction, instead of being positioned corresponding to the anchor 221.

As a result, a size for the anchor 221 to be positioned corresponding to the fixed electrode bonding portion 233 and the movable electrode bonding portion 236 is not needed, hence better miniaturizing the anchor 221.

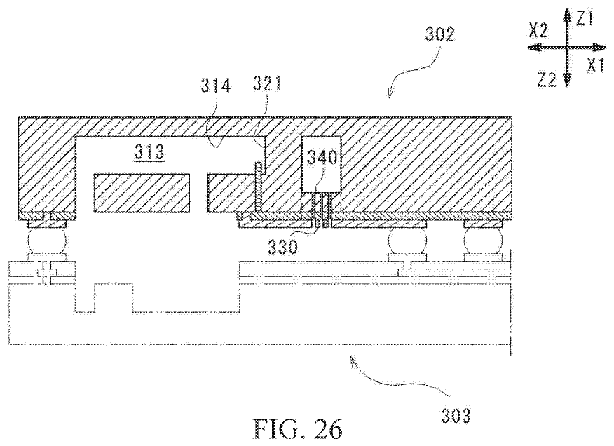

Moreover, FIG. 25 shows a bottom view of a device wafer 302 of yet another variation example, and FIG. 26 shows a cross-sectional diagram of the device wafer 302 in an X-Z plane along the line XXVI-XXVI in FIG. 26. Moreover, a cap wafer 303 corresponding to the device wafer 302 is indicated by a double-dot dashed line in FIG. 26 for reference. As shown in FIG. 25 and FIG. 26, an anchor 321 can also be configured to extend from a bottom surface 314 of a cavity 313 along the Z direction, and a fixed electrode bonding portion 333 and a movable electrode bonding portion 336 are located, for example, on an outer side of the cavity 313, instead of being positioned corresponding to the anchor 321.

In this case, a device wiring 330 may be formed on a flexible structure unit 340 connecting the anchor 321 and a portion at which the fixed electrode bonding portion 333 and the movable electrode bonding portion 336 are provided. Accordingly, a size for the anchor 321 to be positioned corresponding to the fixed electrode bonding portion 333 and the movable electrode bonding portion 336 likewise is not needed, hence better miniaturizing the anchor 321.

### NOTE

The MEMS device and the manufacturing method thereof according to the present disclosure provide the following aspects.

### [Aspect 1]

A MEMS device, comprising a device wafer, a cap wafer and a bonding layer, wherein
the device wafer includes:
   a device substrate, having a first main surface, a second main surface opposite to the first main surface, and a cavity recessed along a first direction from the first main surface toward the second main surface;
   a sensor unit, located within the cavity and mechanically connected to and electrically insulated from the device substrate by a single anchor; and
   a device wiring, electrically coupled to the sensor unit,
the cap wafer includes:
   a cap substrate, facing the device wafer from a side of the first main surface; and
   a cap wiring, electrically coupled to the device wiring,
the bonding layer bonds the device wafer with the cap wafer, and wherein
the device wiring is directly connected to the bonding layer and is electrically coupled to the cap wiring via the bonding layer.

### [Aspect 2]

The MEMS device of Aspect 1, wherein
the sensor unit includes:
   an anchor, fixed to a wall of the cavity;
   a fixed electrode, mechanically connected to the anchor via a first isolation joint, electrically insulated, and extending along a second direction orthogonal to the first direction;
   a spring, mechanically connected to the anchor via a second isolation joint and electrically insulated;
   a mass, mechanically connected and electrically coupled to the spring;
   a movable electrode, mechanically connected and electrically coupled to the mass, extending along the second direction, and facing the fixed electrode along a third direction perpendicular to both the first direction and the second direction; and
   a device insulating layer,
      disposed on at least a region of a proximal side of the first isolation joint in the anchor and the fixed electrode,
      disposed on at least a region spanning the spring, the mass and the movable electrode, and located on a proximal side of the second isolation joint, and
      laminated on the first main surface side,
a portion of the sensor unit other than the anchor is spaced apart from a bottom surface of the cavity along the first direction, wherein
the device wiring includes:
   a fixed electrode wiring,
      laminated on the device insulating layer,
      located corresponding to the fixed electrode when viewed from the side of the first main surface, and electrically coupled to the fixed electrode through the device insulating layer, and
      extending from a fixed electrode contact across the first isolation joint to a fixed electrode bonding portion; and
   a movable electrode wiring,
      laminated on the device insulating layer,
      located corresponding to the spring, the mass or the movable electrode when viewed from the side of the first main surface, and electrically coupled to the spring, the mass or the movable electrode through the device insulating layer, and
      extending from a movable electrode contact across the second isolation joint to the movable electrode bonding portion, wherein
the device wiring is bonded to the cap wiring via the bonding layer at the fixed electrode bonding portion and the movable electrode bonding portion, and
the device wiring is electrically coupled to the cap wiring.

### [Aspect 3]

The MEMS device of Aspect 2, wherein the cap wafer further includes:
a first cap insulating layer, laminated on the cap substrate;
a second cap insulating layer, laminated on the first cap insulating layer, wherein the cap wiring is laminated and interposed between the first cap insulating layer and the second cap insulating layer; and
a bonding electrode, laminated on the second cap insulating layer and is electrically coupled to the cap wiring via a bonding electrode contact penetrating the second cap insulating layer, wherein
the cap wafer is bonded to the fixed electrode bonding portion and the movable electrode bonding portion via the bonding layer at the bonding electrode.

### [Aspect 4]

The MEMS device of Aspect 3, wherein the fixed electrode bonding portion and/or the movable electrode bonding portion are positioned corresponding to the anchor when viewed from the first direction.

### [Aspect 5]

The MEMS device of Aspect 2, wherein
the device wiring is across the anchor when viewed from the first direction,
the fixed electrode bonding portion and/or the movable electrode bonding portion are not located at the anchor when viewed from the first direction.

### [Aspect 6]

The MEMS device of Aspect 3, wherein
the cap wafer includes an electrode pad to which an external wiring is connectable, and
the electrode pad is electrically coupled to an end of the cap wiring opposite to the bonding electrode.

### [Aspect 7]

The MEMS device of Aspect 6, wherein the electrode pad and the cap wiring are located on same layer of the cap wafer and are made of same material.

### [Aspect 8]

The MEMS device of Aspect 1, wherein the bonding layer is made of aluminum germanium alloy.

### [Aspect 9]

The MEMS device of Aspect 1, wherein the device wiring is made of a material having a wettability with respect to the bonding layer and does not cause any eutectic diffusion.

### [Aspect 10]

The MEMS device of Aspect 9, wherein the device wiring is made of a conductive material selected from a group comprising polysilicon, polycide alloy, titanium nitride alloy, and titanium tungsten alloy.

### [Aspect 11]

The MEMS device of Aspect 3, wherein the bonding electrode is made of aluminum alloy.

### [Aspect 12]

The MEMS device of Aspect 1, wherein the anchor extends along the first direction from a bottom wall of the cavity.

### [Aspect 13]

The MEMS device of Aspect 1, wherein the anchor is fixed to a side wall of the cavity, extends along an in-plane direction perpendicular to the first direction, and is spaced apart from a bottom wall of the cavity along the first direction.

### [Aspect 14]

The MEMS device of Aspect 3, wherein
the device wafer includes a device peripheral bonding layer around the cavity, and
the cap wafer includes a cap peripheral bonding layer bonded to the device peripheral bonding layer via the bonding layer.

### [Aspect 15]

The MEMS device of Aspect 14, wherein the device peripheral bonding layer is located on same layer as the device wiring of the device wafer and is made of a material same as a material of the device wiring.

### [Aspect 16]

The MEMS device of Aspect 14, wherein the cap peripheral bonding layer is located on same layer as the bonding electrode of the cap wafer and is made of a material same as a material of the bonding electrode.

### [Aspect 17]

The MEMS device of Aspect 14, wherein the device peripheral bonding layer and the cap outer periphery bonding layer are electrically connectable via the bonding layer.

### [Aspect 18]

The MEMS device of Aspect 17, wherein the cap wafer includes:
a peripheral bonding wiring, electrically coupled to the cap peripheral bonding layer; and
an electrode pad, connected to the peripheral bonding wiring and to which an external wiring is connectable.

### [Aspect 19]

The MEMS device of Aspect 18, wherein
the device peripheral bonding layer is electrically coupled to the device substrate via a device peripheral contact penetrating the device insulating layer, and
the cap periphery bonding layer is electrically coupled to the cap substrate via a cap peripheral contact penetrating the first cap insulating layer.

### [Aspect 20]

A method for manufacturing a MEMS device, comprising:
forming a device wafer including:
   a device substrate, having a first main surface, a second main surface opposite to the first main surface, and a cavity recessed along a first direction from the first main surface to the second main surface;
   a sensor unit, located within the cavity and mechanically connected to and electrically insulated from the device substrate by a single anchor; and
   a device wiring, electrically coupled to the sensor unit; forming a cap wafer including:
   a cap substrate, facing the device wafer from a side of the first main surface; and
   a cap wiring, electrically coupled to the device wiring; and bonding the device wafer and the cap wafer via a bonding layer, wherein
in the bonding, the device wiring is directly connected to the bonding layer and is electrically coupled to the cap wiring via the bonding layer.

1. A MEMS device, comprising a device wafer, a cap wafer and a bonding layer, wherein
the device wafer includes:
a device substrate, having a first main surface, a second main surface opposite to the first main surface, and a cavity recessed along a first direction from the first main surface toward the second main surface;
a sensor unit, located within the cavity and mechanically connected to and electrically insulated from the device substrate by a single anchor; and
a device wiring, electrically coupled to the sensor unit,
the cap wafer includes:
a cap substrate, facing the device wafer from a side of the first main surface; and
a cap wiring, electrically coupled to the device wiring,
the bonding layer bonds the device wafer with the cap wafer, and wherein
the device wiring is directly connected to the bonding layer and is electrically coupled to the cap wiring via the bonding layer.

2. The MEMS device of claim 1, wherein
the sensor unit includes:
an anchor, fixed to a wall of the cavity;
a fixed electrode, mechanically connected to the anchor via a first isolation joint, electrically insulated, and extending along a second direction orthogonal to the first direction;
a spring, mechanically connected to the anchor via a second isolation joint and electrically insulated;
a mass, mechanically connected and electrically coupled to the spring;
a movable electrode, mechanically connected and electrically coupled to the mass, extending along the second direction, and facing the fixed electrode along a third direction perpendicular to both the first direction and the second direction; and
a device insulating layer,
disposed on at least a region of a proximal side of the first isolation joint in the anchor and the fixed electrode,
disposed on at least a region spanning the spring, the mass and the movable electrode, and located on a proximal side of the second isolation joint, and
laminated on the first main surface side,
a portion of the sensor unit other than the anchor is spaced apart from a bottom surface of the cavity along the first direction, wherein
the device wiring includes:
a fixed electrode wiring,
laminated on the device insulating layer,
located corresponding to the fixed electrode when viewed from the side of the first main surface, and electrically coupled to the fixed electrode through the device insulating layer, and
extending from a fixed electrode contact across the first isolation joint to a fixed electrode bonding portion; and
a movable electrode wiring,
laminated on the device insulating layer,
located corresponding to the spring, the mass or the movable electrode when viewed from the side of the first main surface, and electrically coupled to the spring, the mass or the movable electrode through the device insulating layer, and
extending from a movable electrode contact across the second isolation joint to the movable electrode bonding portion, wherein
the device wiring is bonded to the cap wiring via the bonding layer at the fixed electrode bonding portion and the movable electrode bonding portion, and
the device wiring is electrically coupled to the cap wiring.

3. The MEMS device of claim 2, wherein the cap wafer further includes:
a first cap insulating layer, laminated on the cap substrate;
a second cap insulating layer, laminated on the first cap insulating layer, wherein the cap wiring is laminated and interposed between the first cap insulating layer and the second cap insulating layer; and
a bonding electrode, laminated on the second cap insulating layer and is electrically coupled to the cap wiring via a bonding electrode contact penetrating the second cap insulating layer, wherein
the cap wafer is bonded to the fixed electrode bonding portion and the movable electrode bonding portion via the bonding layer at the bonding electrode.

4. The MEMS device of claim 2, wherein the fixed electrode bonding portion and/or the movable electrode bonding portion are positioned corresponding to the anchor when viewed from the first direction.

5. The MEMS device of claim 2, wherein
the device wiring is across the anchor when viewed from the first direction,
the fixed electrode bonding portion and/or the movable electrode bonding portion are not located at the anchor when viewed from the first direction.

6. The MEMS device of claim 3, wherein
the cap wafer includes an electrode pad to which an external wiring is connectable, and
the electrode pad is electrically coupled to an end of the cap wiring opposite to the bonding electrode.

7. The MEMS device of claim 6, wherein the electrode pad and the cap wiring are located on same layer of the cap wafer and are made of same material.

8. The MEMS device of claim 1, wherein the bonding layer is made of aluminum germanium alloy.

9. The MEMS device of claim 1, wherein the device wiring is made of a material having a wettability with respect to the bonding layer and does not cause any eutectic diffusion.

10. The MEMS device of claim 9, wherein the device wiring is made of a conductive material selected from a group comprising polysilicon, polycide alloy, titanium nitride alloy, and titanium tungsten alloy.

11. The MEMS device of claim 3, wherein the bonding electrode is made of aluminum alloy.

12. The MEMS device of claim 1, wherein the anchor extends along the first direction from a bottom wall of the cavity.

13. The MEMS device of claim 1, wherein the anchor is fixed to a side wall of the cavity, extends along an in-plane direction perpendicular to the first direction, and is spaced apart from a bottom wall of the cavity along the first direction.

14. The MEMS device of claim 3, wherein
the device wafer includes a device peripheral bonding layer around the cavity, and
the cap wafer includes a cap peripheral bonding layer bonded to the device peripheral bonding layer via the bonding layer.

15. The MEMS device of claim 14, wherein the device peripheral bonding layer is located on same layer as the device wiring of the device wafer and is made of a material same as a material of the device wiring.

16. The MEMS device of claim 14, wherein the cap peripheral bonding layer is located on same layer as the bonding electrode of the cap wafer and is made of a material same as a material of the bonding electrode.

17. The MEMS device of claim 14, wherein the device peripheral bonding layer and the cap outer periphery bonding layer are electrically connectable via the bonding layer.

18. The MEMS device of claim 17, wherein the cap wafer includes:
a peripheral bonding wiring, electrically coupled to the cap peripheral bonding layer; and
an electrode pad, connected to the peripheral bonding wiring and to which an external wiring is connectable.

19. The MEMS device of claim 18, wherein
the device peripheral bonding layer is electrically coupled to the device substrate via a device peripheral contact penetrating the device insulating layer, and
the cap periphery bonding layer is electrically coupled to the cap substrate via a cap peripheral contact penetrating the first cap insulating layer.

20. A method for manufacturing a MEMS device, comprising:
forming a device wafer including:
a device substrate, having a first main surface, a second main surface opposite to the first main surface, and a cavity recessed along a first direction from the first main surface to the second main surface;
a sensor unit, located within the cavity and mechanically connected to and electrically insulated from the device substrate by a single anchor; and
a device wiring, electrically coupled to the sensor unit;
forming a cap wafer including:
a cap substrate, facing the device wafer from a side of the first main surface; and
a cap wiring, electrically coupled to the device wiring; and
bonding the device wafer and the cap wafer via a bonding layer, wherein
in the bonding, the device wiring is directly connected to the bonding layer and is electrically coupled to the cap wiring via the bonding layer.
